(19) United States
(12) Patent Application Publication
(10) Pub. No.: US 2026/0162745 A1
(43) Pub. Date: Jun. 11, 2026

(54) Memory with Input Data Storage Circuits for Redundancy Shift and Store

(71) Applicant: QUALCOMM Incorporated, San Diego, CA (US)

(72) Inventors: Chulmin JUNG, San Diego, CA (US); Dhvani SHETH, San Diego, CA (US); Seohee KIM, San Diego, CA (US); Anil Chowdary KOTA, San Diego, CA (US)

(21) Appl. No.: 18/977,791

(22) Filed: Dec. 11, 2024

(51) Int. Cl. G11C 29/32; G11C 29/12; G11C 29/24

(52) U.S. Cl. CPC G11C 29/32; G11C 29/1201; G11C 29/24; G11C 2029/3202

(57) ABSTRACT

A memory is provided having a plurality of banks. A shared redundancy address decoder decodes a redundancy address for each of the banks to provide a decoded redundancy address to each bank. A serializer serializes the decoded redundancy address into a serialized decoded redundancy address. Each bank includes scan chain to deserialize the serialized decoded redundancy address to recover its decoded redundancy address. The scan chain includes data input latches that are included within corresponding data input paths to the bank. Should one of the banks have a defect, the bank repairs the defect by reconfiguring its resources responsive to its decoded redundancy address.

### TECHNICAL FIELD

This application relates to memories, and more particularly to a memory having a data input path including input data storage circuits for redundancy address shifting and storing.

### BACKGROUND

A static random-access memory (SRAM) includes an array of bitcells arranged into rows and columns. Each column of bitcells includes a pair of bit lines whereas each row of bitcells includes a word line. As the number of bitcells in each row and column increases, the resulting capacitance of the bit lines and the word lines also increases. This increased capacitance slows memory operation. It is thus conventional to segregate the bitcells into banks, with each bank having its own rows and columns. The resulting bank structure is quite regular and may include numerous bitcells, but the bank structure keeps the word line and bit line capacitance at manageable levels.

To increase density (the number of transistors per a given area of semiconductor die space), the bitcell size, column pitch, and row pitch have all been steadily reduced as SRAMs have evolved from one generation to another. With the extremely small transistor size of modern semiconductor process nodes, it is inevitable that a flaw can be introduced into the memory fabrication. The resulting flaw may affect just a single bitcell in a bank but without any redundancy, an SRAM with a flaw may have to be discarded. It is thus conventional that each bank includes at least one redundant column of bitcells. With regard to this redundant column, the columns of bitcells are arranged in a regular order. Should testing of the memory identify a column with a flaw, the flawed column is excluded from the column order. The column order beginning with the flawed column is then shifted so that the column order includes the redundant column. In this fashion, a memory can be operational despite having a flawed column.

### SUMMARY

In accordance with an aspect of the disclosure, a memory including a first bank is provided in which the first bank includes: a first multiplexed group of columns of bitcells; a second multiplexed group of columns of bitcells; a third multiplexed group of columns of bitcells; a first scan chain configured to shift in a first column redundancy address bit and a second column redundancy address bit; a first input data storage circuit configured to store a first input data signal to be coupled to one of the first multiplexed group of columns of bitcells and the second multiplexed group of columns according to a first column redundancy selection that is responsive to the first column redundancy address bit; and a second input data storage circuit configured to store a second input data signal to be coupled to one of the second multiplexed group of columns of bitcells and the third multiplexed group of bitcells according to a second column redundancy selection that is responsive to the second column redundancy address bit, wherein the first input data storage circuit the second input data storage circuit are both included within the first scan chain.

In accordance with another aspect of the disclosure, a method of using a first input data path in a memory to receive column redundancy address signals is provided that includes: shifting a first column redundancy address signal from a first master latch in a first master-slave latch to a first slave latch in the first master-slave latch to latch the first column redundancy address signal in the first slave latch; configuring the first input data path to couple from the first master latch to a first write driver responsive to the first column redundancy address signal latched in the first slave latch; latching a first input data signal in the first master latch; coupling the first input data signal from the first master latch through the first input data path to the first write driver; and driving the first input data signal from the first write driver to a selected column of bitcells from a first multiplexed group of columns of bitcells.

In accordance with another aspect of the disclosure, a memory is provided that includes: a first global input/output column group; a second global input/output column group; a scan chain including a plurality of master-slave latches arranged serially starting from a first master-slave latch; a first global input/output circuit including a data input latch, wherein the data input latch is configured to function as a master latch in the first master-slave latch; a first multiplexer configured to select between a data input signal and a decoded column redundancy address signal, wherein the first multiplexer includes an output terminal coupled to a data input terminal of the data input latch, and wherein a slave latch in the first master-slave latch is configured to latch a column redundancy address signal from the serialized decoded column redundancy address signal; and a data path configured to couple from an output terminal of the data input latch to a selected one of the first global input/output column group and the second global input/output column group according to a column redundancy selection that is responsive to the column redundancy address signal.

These and additional advantages may be better appreciated through the following detailed description.

### BRIEF DESCRIPTION OF THE DRAWINGS

FIG. 1A is a diagram of an integrated circuit including a memory having a shared column redundancy address decoder for a plurality of banks in accordance with an aspect of the disclosure.

FIG. 1B illustrates an example implementation of the serializer in the memory of FIG. 1A in accordance with an aspect of the disclosure.

FIG. 2 illustrates a shared column redundancy address decoder, a serializer configured to serialize a decoded column redundancy address into a serialized decoded column redundancy address, and a bank including a scan chain configured to deserialize the serialized decoded column redundancy address to recover the decoded column redundancy address in accordance with an aspect of the disclosure.

FIG. 3 is a timing diagram for some signals in a memory having a shared column redundancy address decoder in accordance with an aspect of the disclosure.

FIG. 4 illustrates a bank configured to shift a correspondence between a plurality of global input/output circuits and a plurality of global input/output column groups responsive to a decoded column redundancy address from a shared column redundancy address decoder in accordance with an aspect of the disclosure.

FIG. 5 illustrates a portion of a scan chain for a bank that is integrated with the global input/output circuits for the bank and is configured to deserialize a serialized decoded column redundancy address in accordance with an aspect of the disclosure.

FIG. 6 illustrates some associated circuitry for the scan chain of FIG. 5 in accordance with an aspect of the disclosure.

FIG. 7 illustrates a portion of memory including a scan chain for a bank that is integrated with the global input/output circuits for the bank and is configured to deserialize a serialized decoded column redundancy address in accordance with an aspect of the disclosure.

FIG. 8 illustrates a bank in which the GIO circuits are arranged into a pair of scan chains to decrease the number of clock cycles used to shift in the serialized decoded column redundancy address signal in accordance with an aspect of the disclosure.

FIG. 9 is a flowchart for a method of using an input data path in a memory to receive column redundancy address signals in accordance with an aspect of the disclosure.

FIG. 10 illustrates some example electronic systems including a memory having a shared redundancy address decoder in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

The input/output data signals to banks are typically shared in the form of what is often denoted as global input/output data signals. The global input/output data signals are latched in global input/output (GIO) circuits that are shared by banks. To increase circuit efficiency and reduce semiconductor die space demands, each GIO circuit may latch input/output (IO) signals from a plurality of multiplexed columns in a bank. For example, each GIO circuit may latch IO signals for a pair of columns in an accessed bank in what is denoted as a “MUX2” implementation (MUX being an abbreviated form of multiplexer). In a MUX2 read operation, a data input signal or bit latched in a GIO circuit routes through a read column multiplexer to a selected column from a pair of columns. Similarly, in a MUX2 write operation, a write column multiplexer selects a column from the pair of columns so that a data output signal or bit may be latched in the GIO circuit.

In a MUX4 implementation, the read and write column multiplexers each select a column from four corresponding columns. In a MUX8 implementation, the read and write column multiplexers each select a column from eight corresponding columns. More generally, each read and write column multiplexer selects a column from a corresponding plurality of columns to couple the selected column to the corresponding GIO circuit. Each GIO circuit thus corresponds to a plurality of multiplexed columns denoted herein as a GIO column group. Each bank thus includes a plurality of multiplexed groups of columns that may also be denoted as GIO column groups. The GIO column groups are arranged in order according to the bit significance of the corresponding GIO circuits. For example, suppose that each bank includes a plurality of n GIO circuits arranged from a most-significant-bit GIO circuit to a least-significant-bit GIO circuit, where n is a plural positive integer. Each bank would thus have n corresponding GIO column groups ranging from a most-significant-bit GIO column group to a least-significant-bit GIO column group.

Should the bank have no defective columns, then the correspondence between the GIO circuits and the GIO column groups is unchanged. For example, a data input bit latched into the most-significant-bit GIO circuit would be written to the most-significant-bit GIO column group during a write operation. Similarly, a data output bit retrieved from the least-significant-bit GIO column group would be latched into the least-significant GIO circuit during a read operation. But this one-to-one correspondence between the GIO column groups and the GIO circuits changes should the bank include a defective column in a GIO column group. Should a bank include a defective GIO column group, the bank may shift the correspondence to include a redundant GIO column group. In this shift, the correspondence between some of the GIO column groups and some of the GIO circuits changes due to the error. To identify the GIO column groups with this changed correspondence and any GIO column groups with an unchanged correspondence, a column redundancy address decoder decodes a column redundancy address to produce a decoded column redundancy address that includes at least one bit for each GIO column group. The following discussion will be directed to implementations in which the decoded column redundancy address includes just one bit for each GIO column group, but it will be appreciated that the scope of the disclosure includes implementations in which the decoded column redundancy address includes multiple bits per GIO column group. The shifting of the correspondence between GIO circuits and GIO column groups is triggered by an assertion of a redundancy enable signal for the bank. Should a bank have a plurality of 2ⁿ GIO column groups (n being a positive integer) and its redundancy enable signal is asserted, the bank's column redundancy address decoder decodes an n-bit column redundancy address to identify the erroneous GIO column group. To provide the n-bit column redundancy address and the redundancy enable signal for each bank, a central decoder decodes an address from a non-volatile memory (e.g., a fuse address from a fuse memory). In general, a bank typically may not have a flaw such that its column redundancy address decoder is unused, yet it occupies a substantial amount of semiconductor die space.

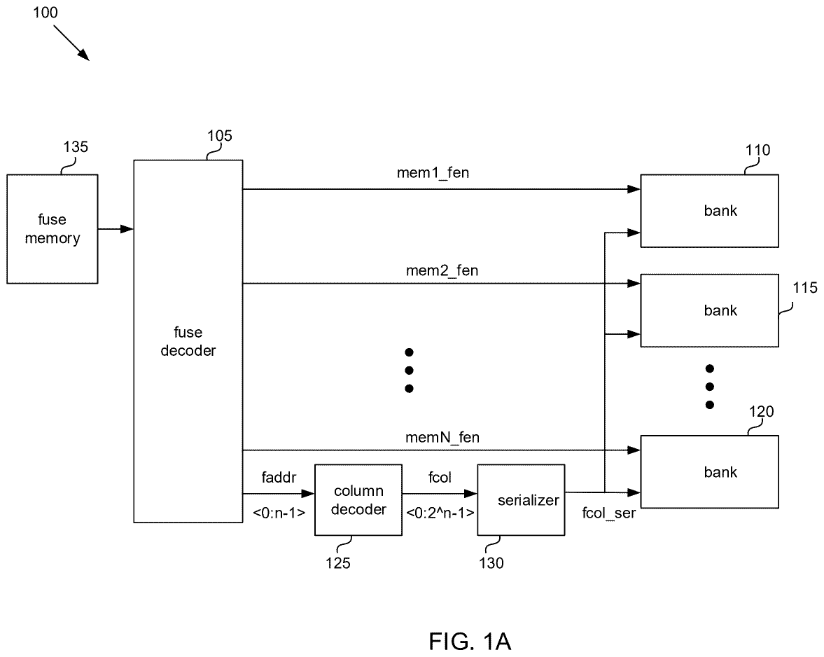

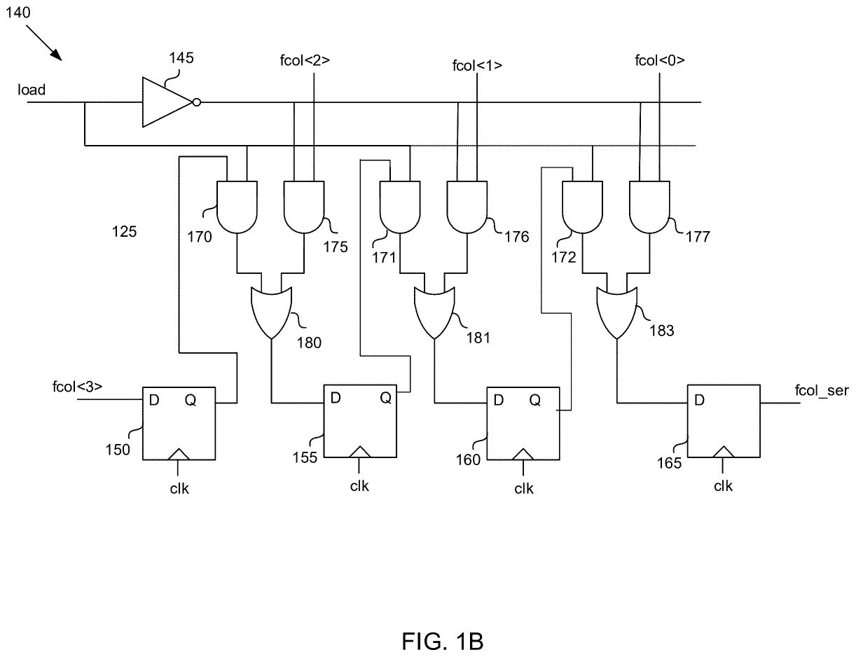

To advantageously increase density, a multi-bank memory is provided in which a redundancy address decoder is shared by a plurality of banks. As defined herein, a redundancy address decoder is deemed to be shared because the redundancy address decoder decodes a redundancy address for each bank in the plurality of banks. In the following discussion, it will be assumed that the shared redundancy address decoder is a shared column redundancy address decoder, but it will be appreciated that other defective features such as a defective row may be addressed by a shared row redundancy address decoder in alternative implementations. An example integrated circuit 100, e.g., a system-on-a-chip (SoC) integrated circuit 100 including a shared column redundancy address decoder 125 for a multi-bank memory is shown in FIG. 1A. The “shared” designation of the address decoder 125 is used herein because the decoder 125 performs the decoding of the column redundancy address for each bank. Each bank thus shares the address decoder 125 in common with the other banks. In particular, the shared column redundancy address decoder 125 decodes a corresponding column redundancy address for each of a plurality of N SRAM banks, where N is a plural positive integer. For illustration clarity, only a first bank 110, a second bank 115, and an Nth bank 120 are shown in FIG. 1A. In the following discussion, it will be assumed that each bank includes 2ⁿ GIO column groups as discussed previously. The shared column redundancy address decoder 125 decodes an n-bit column redundancy address for each bank. The following discussion will assume that a bank's redundancy enable signal is a one-bit signal, but it will be appreciated that additional bits may be used to form the redundancy enable signal in alternative implementations. To begin the decoding of the n-bit column redundancy address and the associated redundancy enable signal for a bank, a non-volatile memory such as a fuse memory 135 stores a fuse address for each bank that is decoded by a central decoder such as a fuse decoder 105. More generally, the central decoder decodes a non-volatile address for each bank.

The fuse decoder 105 decodes the fuse address for a bank into the bank's n-bit column redundancy address and the associated one-bit redundancy enable signal. Since there are N banks in the integrated circuit 100, the fuse decoder 105 produces N corresponding redundancy enable signals to identify whether each of the N banks has a defective column. For the first bank 110, the corresponding redundancy enable signal is designated as mem1_fen. Similarly, the redundancy enable signal for the second bank 115 is designated as mem2_fen. In this fashion, the redundancy enable signal for the Nth bank 120 is designated as memN_fen.

Should the redundancy enable signal for a bank be asserted in a traditional integrated circuit without shared redundancy decoding, the bank's column redundancy address decoder would then decode its n-bit column redundancy address. But including a column redundancy address decoder in each bank demands a significant amount of semiconductor die space. This die space demand is reduced in the integrated circuit 100 through the use of the shared column redundancy address decoder 125 that decodes an n-bit column redundancy address faddr<0:n−1> for each bank. For each bank, the shared column redundancy address decoder 125 decodes the corresponding n-bit column redundancy address faddr<0:n−1> into a decoded column redundancy address signal fcol<0:2ⁿ⁻¹>. In that regard, the GIO column groups may be arranged in a bit-significance order from a (2-1)th GIO column group to a zeroth GIO column group. Suppose that the ith GIO column group in this column order is defective, where i is an integer satisfying the inequality 0≤i≤2ⁿ⁻¹. Since the ith GIO column group is defective, its role in the column order is taken by an (i−1)th GIO column group. The column group order has thus shifted at the defective ith GIO column group by one such that a redundant GIO column group assumes the role of the zeroth GIO column group. The default GIO column group order has shifted by one from the ith GIO column group to the zeroth GIO column group whereas the preceding GIO column groups from the (2ⁿ⁻¹)th GIO column group to a (i+1)th GIO column group are unshifted.

To identify whether a GIO column group's correspondence has been shifted or not due to the presence of a defective column, the decoded column redundancy address signal fcol<0:2ⁿ⁻¹> includes a bit for each GIO column group. The bits for the shifted GIO column groups are asserted whereas the bits for the unshifted GIO column groups are not asserted (note that this convention could be reversed such that the bits for the unshifted columns could be asserted in alternative implementations). As defined herein, a binary signal is deemed to be asserted if the binary signal is true, regardless of whether the true binary state is represented by an active-high or active-low convention. In an active-high convention, a binary signal (a bit) is asserted by being charged to a power supply voltage whereas it is de-asserted by being grounded. Conversely, a binary signal is asserted by being grounded in an active-low convention.

The shared column redundancy address decoder 125 may be deemed to form a means for serially decoding a redundancy address for each bank to provide the decoded redundancy address for the bank. Although the shared column redundancy address decoder 125 has advantageously increased density, the 2ⁿ bits in the decoded column redundancy address signal fcol<0:2ⁿ⁻¹> raises a routing issue to each bank. The decoded column redundancy address signal fcol<0:2ⁿ⁻¹> is a parallel signal in that its 2ⁿ bits are all produced by the shared column redundancy address decoder 125 simultaneously. To propagate a parallel signal from the shared column redundancy address decoder 125 to a bank thus requires a wire or lead for each bit. In general, each bank will not include a defective GIO column group but to address the possibility that the bank could include a defective column, each bank should be able to receive the corresponding decoded column redundancy address signal fcol<0:21-1> from the shared column redundancy address decoder 125. Since there are N banks and each decoded column redundancy address signal fcol<0:2ⁿ⁻¹> is 2ⁿ bits wide, a routing of a total of N*2ⁿ signals could be required between the shared column redundancy address decoder 125 and the banks. Should each signal propagate on its own wire or lead, the resulting routing of so many signals could lead to routing congestion and design complications.

To address the routing issues from the introduction of the shared column redundancy address decoder 125, the integrated circuit 100 includes a serializer 130 that serializes the decoded column redundancy address signal fcol<0:2ⁿ⁻¹> into a serialized decoded column redundancy address signal (fcol_ser). As defined herein, a serialized signal is a multi-bit signal in which the bits are not presented simultaneously but instead propagate one bit at a time. The serialized decoded column redundancy address signal may thus propagate from the serializer 130 over a single wire or lead that bifurcates in some implementations into N leads, one for each of the N banks. The serializer 130 is thus quite advantageous as the routing complexity of routing N*2ⁿ signals is collapsed into merely routing the serialized decoded column redundancy address signal.

The serializer 130 may be implemented in multiple ways as known in the serialization arts. For example, serializer 130 may be implemented as a parallel-in serial-out (PISO) shift register 140 as shown in FIG. 1B. For the PISO shift register 140, the number of bits for the width of the decoded column redundancy address signal fcol is four such that the decoded column redundancy address signal fcol ranges from a most-significant bit fcol<3> to a least-significant-bit fcol<0>. The PISO shift register 140 includes one flip-flop for each bit in the decoded column redundancy address signal fcol ranging from a flip-flop 150 to a flip-flop 165. The flip-flops are loaded with the corresponding bits from the decoded column redundancy address signal fcol during a load phase while an active-low load signal is asserted by being grounded. The load signal drives an input terminal of an AND gate 170, an AND gate 171, and an AND gate 172. An output signal from each of the AND gates 170, 171, and 172 will be zero during the load phase. An inverter 145 inverts the load signal to drive an input terminal of an AND gate 175, an AND gate 176, and an AND gate 177 with the inverted load signal. The AND gate 175 ANDs the fcol<2> bit with the inverted load signal. Similarly, the AND gate 176 ANDs the fcol<1> bit with the inverted load signal. In the same fashion, the AND gate 177 ANDs the fcol<0> bit with the inverted load signal. Since the inverted load signal is a logical one during the load signal, the AND gates 175, 176, and 177 will each pass their respective fcol bit.

An OR gate 180 ORs the output signals from the AND gates 170 and 175. The output signal from the AND gate 170 is zero during the load phase due to the load signal being asserted low. The OR gate 180 will thus pass the fcol<2> bit to a data input terminal (D) of a flip-flop 155. Similarly, an OR gate 181 ORs the output signals from the AND gates 171 and 176. The output signal from the AND gate 171 is zero during the load phase due to the load signal being asserted low. The OR gate 181 will thus pass the fcol<1> bit to a data input terminal (D) of a flip-flop 160. Finally, an OR gate 183 ORs the output signals from the AND gates 172 and 177. The output signal from the AND gate 172 is zero during the load phase due to the load signal being asserted low. The OR gate 183 will thus pass the fcol<0> bit to a data input terminal (D) of the flip-flop 165.

The flip-flop 150 receives the fcol<3> bit at its data input terminal. Each of the flip-flops 150, 155, 160, and 165 is clocked by a clock signal clk. The flip-flop 150 will thus latch the fcol<3> bit during the load phase when the clock signal clk is asserted (has a rising edge from ground to a power supply voltage). At the same time, the flip-flops 155, 160, and 165 will latch the fcol bits fcol<2>, fcol<1>, and fcol<0>, respectively. It may thus be seen that the PISO shift register 140 is loaded with the decoded column redundancy address signal fcol during the load phase in response to the assertion of the clock signal. A shift phase may then ensue through a de-assertion of the load signal. Since the load signal is active-low in this implementation, it is asserted by being charged to a power supply voltage. The inverted load signal will thus be a logic zero, which causes the output signals of the AND gates 175, 176, and 177 to all be logical zeroes.

Since the load signal is a logic one and the output signal from the AND gate 175 is a logic zero in the shift phase, a latched Q output signal from the flip-flop 150 will pass through the AND gate 170 and the OR gate 180 to drive the data input terminal (D) of the flip-flop 155. Similarly, a latched Q output signal from the flip-flop 155 will pass through the AND gate 171 and the OR gate 181 to drive a data input terminal (D) of the flip flop 160. In the same fashion, a latched Q output signal form the flip-flop 160 will pass through the AND gate 172 and the OR gate 183 to drive the data input terminal (D) of the flip-flop 165, which produces the serial signal fcol_ser at its Q output terminal. In one clock cycle during the shift phase, the latched contents of the PISO shift register 140 shifts by one bit. Should a PISO shift register be n bits in length, it may thus be seen that one clock cycle is used to load the PISO shift register and n clock cycles are used to shift out the serial signal fcol_ser. It will be appreciated that the PISO shift register 140 is merely one implementation of many alternatives that may be used to serialize the decoded column redundancy address signal fcol.

Referring again to the fuse decoder 105 (FIG. 1A), it may be seen that it also functions serially on the various fuse addresses for the banks. For example, a fuse address for the first bank 110 may be initially decoded. Should the redundancy enable signal mem1_fen then be asserted, the shared column redundancy address decoder 125 may decode the n-bit column redundancy address faddr<0:n−1> for the first bank 110 into the decoded column redundancy address signal fcol<0:2ⁿ⁻¹> for the first bank 110. The serializer 130 may then form the serialized decoded column redundancy address signal fcol_ser for the first bank 110.

The fuse decoder 105 may then decode a fuse address for the second bank 115. Should the redundancy enable signal mem2_fen then be asserted, the shared column redundancy address decoder 125 may decode the n-bit column redundancy address faddr<0:n−1> for the second bank 115 into the decoded column redundancy address signal fcol<0:2ⁿ⁻¹> for the second bank 115. The serializer 130 may then serialize the decoded column redundancy address signal to form the serialized decoded column redundancy address signal fcol_ser for the second bank 115. This process may then be repeated for any other bank that includes a defective column. For example, the fuse decoder 105 may then decode a fuse address for the Nth bank 120. Should the redundancy enable signal memN_fen be asserted, the shared column redundancy address decoder 125 may decode the n-bit column redundancy address faddr<0:n−1> for the Nth bank 120 into the decoded column redundancy address signal fcol<0:2ⁿ⁻¹> for the Nth bank 120. The serializer 130 may then serialize the decoded column redundancy address signal to form the serialized column redundancy address signal fcol_ser for the Nth bank 120.

Although the serialization of each of the decoded column redundancy address signals fcol<0:2ⁿ⁻¹> cases the routing to banks, each bank then needs to deserialize its serialized decoded column redundancy address signal fcol_ser should the corresponding redundancy enable signal be asserted. To advantageously reuse existing circuits, the deserialization may exploit the scan chain within each bank. Each bank's scan chain is formed by a serial chain of storage elements such as a serial chain of flip-flops forming a shift register. As used herein, the terms flip-flop and latch are used interchangeably. During a scan mode of operation, various input vectors are scanned through the bank's scan chain to test the operation of the bank such as standardized under the Joint Test Action Group (JTAG) specification.

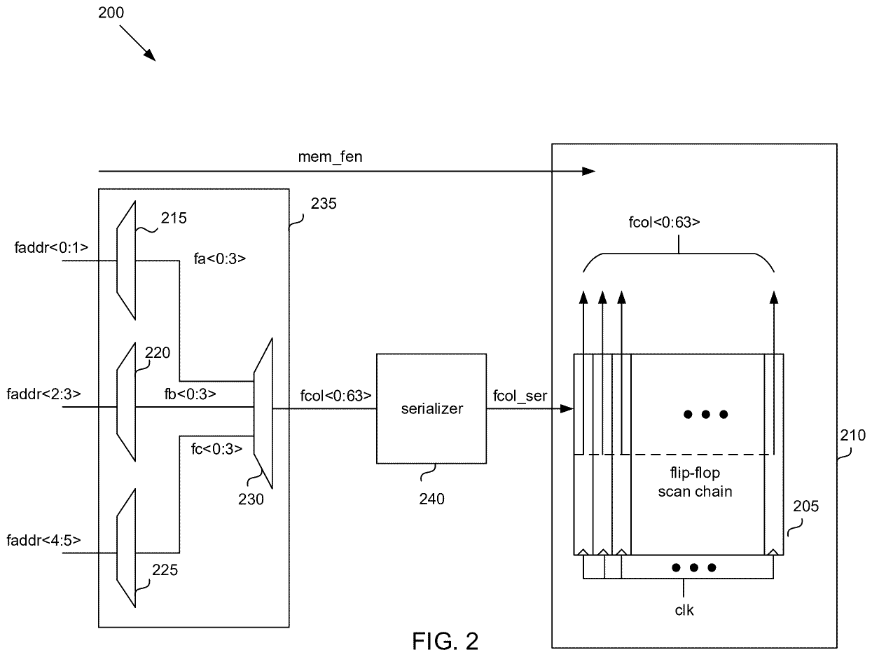

An example scan chain 205 in an SRAM bank 210 in an integrated circuit 200 with a shared column redundancy address decoder 235 is shown in FIG. 2. For illustration clarity, the fuse memory, the fuse decoder, and additional banks are not shown in FIG. 2. The bank 210 includes sixty-four GIO column groups (not illustrated) such that the shared column redundancy address decoder 235 decodes a six-bit column redundancy address faddr<0:5>. To case the decoding complexity, the shared column redundancy address decoder 235 may use a two-level decoding. A first-level decoding uses predecoders 215, 220, and 225. The six-bit column redundancy address faddr<0:5> is thus split into three two-bit address signals, one for each predecoder. In particular, the predecoder 215 decodes two address bits faddr<0:1> into a four-bit signal fa<0:3>. Similarly, the predecoder 220 decodes two address bits faddr<2:3> into a four-bit signal fb<0:3>. Finally, the predecoder 225 decodes two address bits faddr<4:5> into a four-bit signal fc<0:3>. A final decoder 230 decodes the three four-bit signals fa<0:3>, fb<0:3>, and fc<0:3> to form a decoded column redundancy address signal fcol<0:63>. In other implementations, the shared column redundancy address decoder 235 may use a decoding scheme having different number of levels (e.g., 3, 4, etc.). A serializer 240, coupled between the shared column redundancy address decoder 235 and the bank 210, serializes the decoded column redundancy address signal fcol<0:63> into the serialized decoded column redundancy address signal fcol_ser having sixty-four bits.

The bank 210 includes a shift register scan chain such as a flip-flop scan chain 205. During a scan mode, the flip-flop scan chain 205 serially shifts an input vector and/or an output vector as known in the scan mode arts. But should the bank 210 have a defective column during normal operation such that the bank 210 receives an asserted redundancy enable signal mem_fen, the serialized decoded column redundancy address signal fcol_ser is shifted into the flip-flop scan chain 205. In that regard, the scan chain 205 includes a storage element such as a flip-flop for each GIO column group in the bank 210. Since bank 210 has a GIO column group order spanning sixty-four GIO column groups, there are sixty-four corresponding flip-flops in the flip-flop scan chain 205. With the sixty-four-bit serialized decoded column redundancy address signal fcol_ser fully shifted into the scan chain 205, a functional mode of operation with column redundancy may proceed as each GIO column group has a corresponding bit from the serialized decoded column redundancy address signal fcol_ser to control its redundancy. The scan chain 205 deserializes the serialized decoded column redundancy address signal fcol_ser to recover the decoded column redundancy address signal fcol<0:63>.

As will be discussed further herein, the scan chain 205 may be integrated with the data path to the GIO column groups in the bank 210. Regardless of whether the scan chain 205 is so integrated, the shifting within the scan chain is responsive to a memory clock signal (clk). At each cycle of the clock signal, the serialized decoded column redundancy address signal fcol_ser shifts by one bit into the scan chain 205. Referring again to integrated circuit 100 of FIG. 1A, the shifting of the serialized decoded column redundancy address signal fcol_ser into one of the bank's scan chain 205 thus takes n clock cycles should the serialized column redundancy address signal fcol_ser be one-bit wide. This shifting time may be reduced by increasing the width of the serialized decoded column redundancy address signal fcol_ser as will be explained further herein.

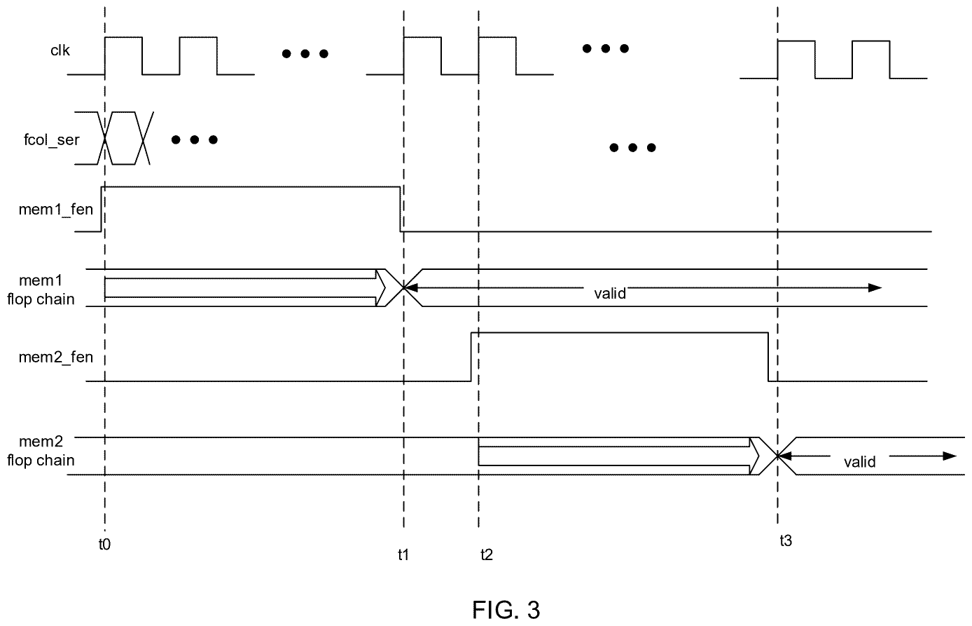

Referring again to FIG. 1A, the decoding by the fuse decoder 105 is serially performed with respect to the banks. It is arbitrary how the banks are ordered with respect to this decoding, but it will be assumed herein that the decoding order starts with the first bank 110. The fuse decoder 105 may thus initially decode the fuse address for the first bank 110 to produce the first bank's redundancy enable signal mem1_fen and the column redundancy address faddr<0:n−1> for the first bank 110. The fuse decoder 105 may then decode the fuse address for the second bank 115 and so on such that the fuse decoder 105 ends by decoding the fuse address for the Nth bank 120. A timing diagram for the decoding for the first bank 110 and for the second bank 115 is shown in FIG. 3. At a time t0, the fuse decoder 105 (shown only in FIG. 1A) asserts the first bank's redundancy enable signal mem1_fen. At the same time, the shared column redundancy address decoder 125 decodes the column redundancy address for the first bank 110 to produce the decoded column redundancy address signal fcol<0:2ⁿ⁻¹> that is serialized by the serializer 130 to produce the serialized decoded column redundancy address signal fcol_ser for the first bank 110. The serialized decoded column redundancy address signal fcol_ser shifts into the scan chain (mem1 flop chain) for the first bank 110 responsive to cycles of the clock signal clk. At a time t1, all the bits for the serialized decoded column redundancy address signal fcol_ser have shifted into the mem1 flop chain so that the decoded column redundancy information is valid for the first bank 110.

The fuse decoder 105 may then decode the fuse address for the second bank 115 to assert the second bank's redundancy enable signal mem2_fen at a time t2. At the same time, the fuse decoder 105 also decodes the fuse address into the column redundancy address faddr<0:n−1> for the second bank 115. The shared column redundancy address decoder 125 may then decode the column redundancy address for the second bank 115 to produce the decoded column redundancy address signal fcol<0:2ⁿ⁻¹> that is serialized by the serializer 130 to produce the serialized decoded column redundancy address signal fcol_ser for the second bank 115. The serialized decoded column redundancy address signal fcol_ser shifts into the scan chain (mem2 flop chain) for the second bank 115 responsive to cycles of the clock signal clk. At a time t3, all the bits for the serialized decoded column redundancy address signal fcol_ser have shifted into the mem2 flop chain so that the decoded column redundancy information is valid for the second bank 115. In general, if the serialized decoded column redundancy address signal fcol_ser is one-bit wide and a bank has a plurality of n GIO column groups, the scan chain shifting uses n clock cycles to shift in a bank's serialized decoded column redundancy address signal fcol_ser into the bank's scan chain. Another clock cycle accounts for the fuse decoding, column redundancy address decoding, and serialization for the bank. With the serialized decoded column redundancy address signal shifted into the banks, the redundancy logic for each GIO column group may configure a corresponding switch matrix as will be explained further herein. A redundancy setup mode is then complete such that the functional mode may begin with either a read or write operation. The redundancy setup mode thus spans from the fuse decoding, the decoding in the shared column redundancy address decoder, the serialization of the decoded column redundancy address signals to form the serialized decoded column redundancy address signals, the shifting of the serialized decoded column redundancy address signals into the banks to recover the corresponding decoded column redundancy address signals, the redundancy logic processing, and the resulting configuration of the switch matrices.

The integration of the scan chain for a bank with the bank's input/output data path that is used during write and read operations will now be discussed in more detail. The input/output data path includes an input/output circuit (e.g., a GIO circuit) having an input storage element (e.g., an input flip-flop) that during a write operation latches an input data bit that will be written to a selected column. The GIO circuit also includes an output storage element (e.g., an output flip-flop or output latch) that latches an output data bit from a read operation. Should an input/output circuit not be shared with another bank, it may be referred to as a local input/output circuit. But it is often more efficient for an input/output circuit to be shared across a pair of banks. Such a shared input/output circuit is typically denoted as a global input/output (GIO) circuit as noted earlier. The following discussion will thus be directed to implementations in which the input/output circuits are GIO circuits without loss of generality.

Regardless of whether an input/output circuit is global or local, an input/output circuit is typically shared across a multiplexed group of columns through a read column multiplexer and a write column multiplexer. The write column multiplexer selects from the multiplexed group of columns for a write operation. In the write operation, the input flip-flop in the global input/output circuit couples through a write driver to the write column multiplexer. The write column multiplexer selects a column from the multiplexed group of columns so that the write driver may write to a bitcell in the selected column through the selected column's bit line pair. Similarly, the read column multiplexer selects from the multiplexed group of columns for a read operation. In the read operation, a sense amplifier couples through the read column multiplexer to a bitcell in the selected columns through the selected column's bit line pair to sense the data output bit. The output storage element in the global input/output circuit then latches the data output bit from the sense amplifier.

With respect to the column multiplexing, a combination of the write driver, the write column multiplexer, the read column multiplexer, and the sense amplifier may be denoted as a local data path for a given global IO data signal. A combination of the local data path and the multiplexed group of columns is denoted herein as a “GIO column group” to emphasize the bit line multiplexing aspect. Each multiplexed column within a GIO column group includes a bit line pair and a plurality of bitcells. Given this convention, it may be appreciated that rather than have a single redundant column, a bank may instead include at least one redundant GIO column group. The number of columns in the redundant GIO column group depends upon the column multiplexing in the corresponding bank. Should the bank's GIO column groups each include a pair of columns such that the corresponding read and write column multiplexers are each multiplexing a pair of columns, then the redundant GIO column group includes a pair of columns. Similarly, should the bank's GIO column groups each include four columns such that the corresponding read and write column multiplexers are each multiplexing four corresponding columns, then the redundant GIO column group includes four columns. More generally, if the column multiplexing for a bank be an M to one column multiplexing, where M is a power of two (2, 4, 8, and so on), then the redundant GIO column group may include M columns.

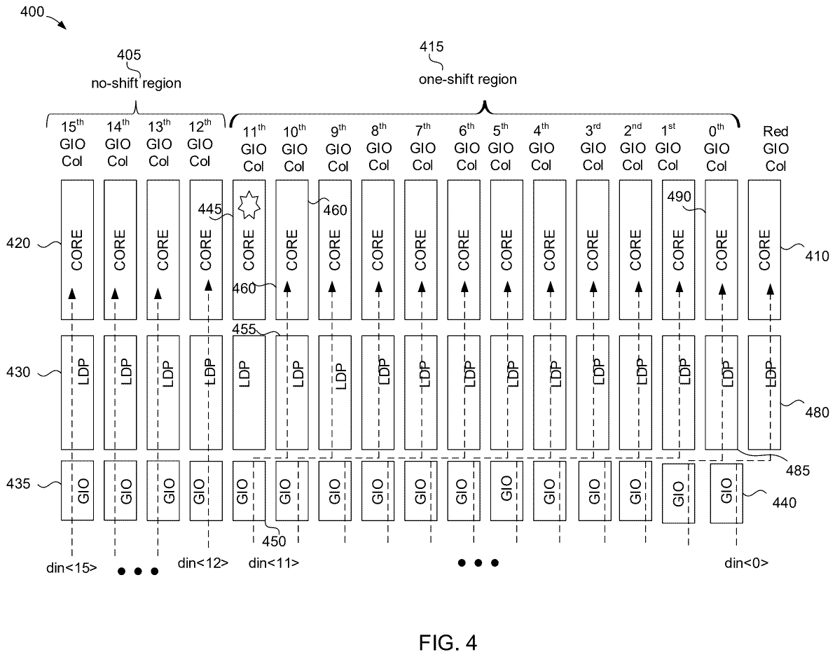

The number of GIO circuits that may access a given bank depends upon the implementation. For example, should a bank have sixteen GIO column groups, then there are sixteen corresponding GIO circuits. More generally, if a bank has a plurality of n GIO column groups, then there is a plurality of n corresponding GIO circuits. The redundancy shifting in a bank discussed earlier with respect to the decoded column redundancy address signal fcol<0:2ⁿ⁻¹> is thus a shifting with respect to the correspondence between the GIO circuits and the GIO column groups. This may be better understood with respect to a bank 400 shown in FIG. 4. In this implementation, there are sixteen global input/output circuits ranging from in GIO bit significance from a fifteenth GIO circuit 435 to a zeroth GIO circuit 440. Without any defective columns, each GIO circuit couples to a corresponding GIO column group ranging from a zeroth GIO column group (0^{th} GIO Col) to a fifteenth GIO column group (15^{th} GIO Col). Each GIO column group includes a core of columns of bitcells. The number of columns of bitcells within each core depends upon the column multiplexing. For example, each core may include a pair of multiplexed columns of bitcells (a MUX2 implementation). Similarly, each core may include four multiplexed columns of bitcells (a MUX4 implementation). Each GIO column group also includes a local data path as defined earlier. For example, the zeroth GIO column group of columns includes a zeroth core 490 and a zeroth local data path 485. Similarly, the fifteenth GIO column group includes a fifteenth core 420 and a fifteenth local data path 430.

Should the bank 400 have no defective columns, each GIO circuit couples through the corresponding local data path to a selected column in the corresponding core during a read operation or a write operation. For example, the zeroth GIO circuit 440 couples through the zeroth local data path 485 to a selected column in the zeroth core 490. In a write operation, a zeroth data input bit din<0> is latched within the zeroth GIO circuit 440 so that it may then be coupled through the zeroth local data path 485 to the selected column in the zeroth core 490. Similarly, the fifteenth GIO circuit 435 couples through the fifteenth local data path 430 to a selected column in the fifteenth core 420. In a write operation, a fifteenth data input bit din<15> is latched in the fifteenth GIO circuit 435 so that it may then be coupled through the fifteenth local data path 430 to the selected column in the fifteenth core 420. But if the bank 400 includes a defective column, the IO coupling between the GIO circuits and the GIO column groups shifts. For example, suppose that an eleventh core 445 in an eleventh GIO column group (11^{th} GIO Col) includes a defective column. Without this defect, an eleventh GIO circuit 450 would couple to a selected column in the eleventh core 445 during a read operation or a write operation. For example, an eleventh input data bit din<11> that was latched in the eleventh GIO circuit 450 couples to a selected column in the eleventh core 445 during a write operation. But with the defect, a redundancy logic circuit (not illustrated) shifts the coupling such as through a switch matrix (not illustrated) so that the eleventh input data bit din<11> from the eleventh GIO circuit 450 instead couples though a tenth local data path 455 for a tenth GIO column group (10^{th} GIO Col) to a selected column in a tenth core 460. The redundancy logic circuit and associated switching matrix for a GIO column group may be located between the group's GIO circuit and the group's local data path. The input data flow or the output data flow ranging from the eleventh GIO circuit 450 to the zeroth GIO circuit 440 thus shifts by one GIO column group. The zeroth GIO circuit 440 thus couples through a redundant local data path 480 to a selected column in a redundant core 410 for a redundant GIO column group (Red GIO Col).

It may thus be seen that the GIO column groups may be divided into a no-shift region 405 and a one-shift region 415 depending upon the location of the defective column. In the no-shift region 405, each GIO circuit couples through the corresponding local data path to a selected column in the corresponding core. But in the one-shift region, this coupling from the GIO circuit to a core is shifted by one GIO column group. Since the defective column in bank 400 is within the eleventh GIO column group, the fifteenth GIO column group through a twelfth GIO column group are in the no-shift region 405. The one-shift region 415 extends from the eleventh GIO column group to the zeroth GIO column group. Each redundancy logic circuit for each GIO column group responds to the corresponding bit (or bits) in the decoded column redundancy address signal fcol discussed earlier. Should the bit be unasserted, the GIO column group remains in the default no-shift region 405. But if the bit is asserted, the GIO column group is part of the one-shift region 415.

It will be appreciated that the shared redundancy decoding disclosed herein may be extended to implementations in which a bank includes two redundant GIO column groups. In such implementations, the GIO column groups may be divided into a no-shift region, a one-shift region, and a two-shift region (assuming that there are two defective GIO column groups in the bank). The no-shift and one-shift regions may function as described with respect to bank 400. In the two-shift region, the GIO circuit couples to a GIO column group that is shifted down by two GIO column groups in the GIO column group order. For example, an ith GIO circuit couples to a (i−2)th GIO column group, where i is the integer index of the 2^{nd} defective GIO column group. In such double redundancy implementations, the decoded column redundancy address signal would include at least two bits for each GIO column group to identify whether the GIO column group is in the no-shift, one-shift, or two-shift region.

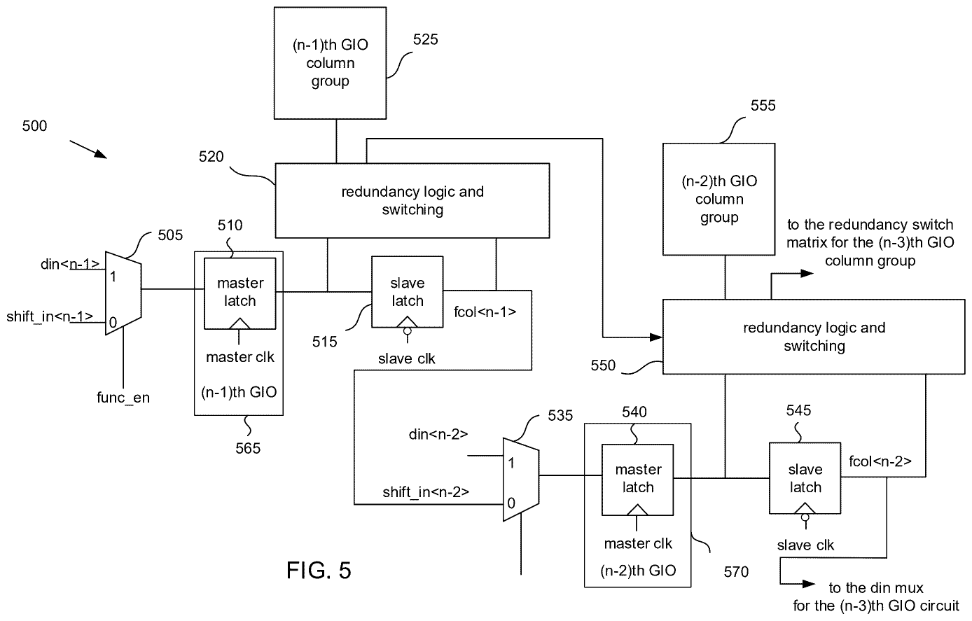

With these redundancy concepts in mind, a data input path for a bank in which the column redundancy is controlled by a shared column redundancy address decoder will now be discussed that advantageously integrates the input latch in the corresponding GIO circuits with a scan chain that also functions to shift in the serialized decoded column redundancy address signal fcol_ser. An example data input path integrated with a scan chain 500 is shown in FIG. 5 for a bank 500. For illustration clarity, only a portion of data input path/scan chain 500 is shown for an (n−1)th GIO column group 525 and an (n−2)th GIO column group 555. The scan chain 500 passes through a master latch in each GIO circuit. Each master latch functions as the GIO circuit's input data latch. The scan chain 500 begins at a master latch 510 in an (n−1)th GIO circuit 565. A subsequent (n−2)th GIO circuit 570 including a master latch 540 is also shown in FIG. 5 but the remaining GIO circuits are not shown for illustration brevity. If there are a plurality of n GIO circuits (n being a plural positive integer) for a bank, then the scan chain 500 passes through n master latches. As will be discussed further herein, a scan chain may be split into serial portions to reduce the clock cycles needed to shift in the serialized decoded column redundancy address signal fcol_ser for the redundancy information. In scan chain 500, there is no segmentation such that the scan chain 500 begins with the (n−1)th master latch 510 and ends with a zeroth master latch and slave latch (not illustrated). It thus takes n clock cycles of a master clock signal (master clk) that clocks the master latches to shift the entire serialized decoded column redundancy address signal fcol_ser into the scan chain 500.

There are three modes of operation for the scan chain 500. In the scan mode of operation, a scan-in (sin) signal shifts into the scan chain 500. In the redundancy setup mode of operation, the serialized decoded column redundancy address signal fcol_ser shifts into the scan chain 500. Finally, during the functional mode of operation in which read or write operations occur, each master latch functions as the data input latch for the corresponding GIO circuits. Since it is generic to the scan chain 500 whether the shifted-in signal is a scan-in signal or the serialized decoded column redundancy address signal fcol_ser, the shifted-in signal is denoted in FIG. 5 as an n-bit shift-in signal. To allow the selection between a data input signal (din) or the shift-in signal to each master latch, a data input terminal for each master latch receives a selected signal from a corresponding multiplexer. For example, the initial master latch 510 in the scan chain 500 latches a selected signal from a multiplexer 505. A functional mode enable signal (func_en) controls the multiplexer 505 to select for an (n−1)th data input signal (din<n−1>) during a functional mode write operation. Should there be no errors in the (n−1)th GIO column group, the din<n−1> signal couples to a selected column's bitcell (not illustrated) in the (n−1)th GIO column group 525 as will be further explained herein.

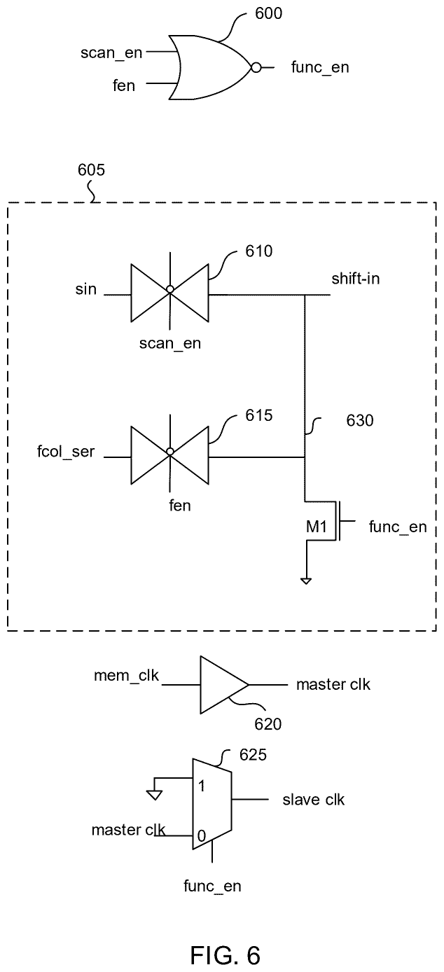

The data input signals (e.g., the din<n−1> signal) are not shifted through the scan chain 500. To allow the shift-in signal to shift through the scan chain and prevent the data input signals from similarly shifting, each master latch in the scan chain 500 is associated with a corresponding slave latch. For example, a slave latch 515 latches the shift-in signal from the master latch 510 during either the scan mode or during the redundancy setup mode. Similarly, a slave latch 545 latches the shift-in signal from the master latch 540. As known in the master/slave latch arts, each slave latch latches the bit stored in the corresponding master latch on the opposite clock edge that clocks the master latch. However, if the master clock signal were used to clock the slave latches, the data input signals would be undesirably shifted through the scan chain 500. To prevent this shifting, the master clock signal may be gated such as by a multiplexer 625 shown in FIG. 6 to produce a slave clock signal (slave clk) that clocks the slave latches. The functional mode enable signal (func_en) controls the multiplexer 625 to select for ground during the functional mode to ground the slave clock signal. In this fashion, the data input signals latched in the master latches during the functional mode are not shifted through the scan chain 500.

During either the scan mode or the redundancy setup mode, the master clock signal passes through the multiplexer 625 to form the slave clock signal. The shift-in signal latched in the master latches is then latched by the corresponding slave latches since the slave latches are then clocked. Since each master latch latches on a rising edge of the master clock signal whereas each slave latch latches on the falling edge of the slave clock signal, it takes one cycle of the master clock signal to shift the shift-in signal through a given one of the master/slave latch combinations.

During the scan mode of operation, a scan enable signal (scan_en) is asserted to force the scan-in signal to form the shift-in signal that will be shifted through the scan chain 500. Conversely, a redundancy setup enable signal (fen) is asserted during the redundancy setup mode in which the serialized decoded column redundancy address signal shifts through the scan chain 500. With the redundancy setup mode complete, the redundancy shifting between the GIO circuits and the GIO column groups is setup for a subsequent functional mode of operation as will be discussed further herein.

As shown in FIG. 6, a selection circuit 605 responds to the scan_en and fen signals to select whether the shift-in signal is the scan-in signal (sin) or the serialized decoded column redundancy address signal (fcol_ser). To either pass or block the scan-in signal from forming the shift-in signal, the scan-in signal is received by a switch such as a transmission gate 610 controlled by the scan enable signal (scan_en). With the scan enable signal asserted during the scan mode, the transmission gate 610 passes the scan-in signal to form the shift-in signal. But during either the functional mode or the redundancy setup mode, the transmission gate 610 is blocked to prevent the scan-in signal from affecting the shift-in signal. Similarly, a transmission gate 615 controls whether the serialized decoded column redundancy address signal (fcol_ser) passes to form the shift-in signal. The transmission gate 615 opens in response to an assertion of the redundancy setup enable signal (fen) to pass fcol_ser and is closed otherwise. To ground the shift-in signal during the functional mode, a node 630 for the shift-in signal couples through an n-type metal-oxide semiconductor (NMOS) transistor M1. The functional mode enable signal (func_en) drives a gate of the transistor M1 so that the node 630 is grounded during the functional mode. A logic gate such as a NOR gate 600 may process the scan enable (scan_en) and the redundancy setup enable (fen) signals to form the functional mode enable signal (func_en).

Referring again to the scan chain 500, the shift-in signal will thus be the serialized decoded column redundancy address signal (fcol_ser) during the redundancy setup mode. After n cycles of the master clock, the scan chain 500 will have shifted in the entire serialized decoded column redundancy address signal (fcol_ser). A slave latch for the zeroth GIO column group (not illustrated) will then have latched the zeroth bit of the decoded column redundancy address signal (fcol<0>). Similarly, the slave latch 545 will have latched the (n−2)th bit of the decoded column redundancy address signal (fcol<n−2>). Finally, the slave latch 515 latches the (n−1)th bit of the decoded column redundancy address signal (fcol<n−1>).

Each GIO column group associates with a corresponding redundancy logic circuit and a redundancy switch matrix to respond to the decoded column redundancy address signal. For example, a redundancy logic and switching circuit 520 responds to the decoded column redundancy address signal (fcol<n−1>) to control whether the data input signal din<n−1> couples from the master latch 510 to a selected column in the (n−1)th GIO column group 525. Similarly, a redundancy logic and switching circuit 550 responds to the decoded column redundancy address signal (fcol<n−2>) to control whether the data input signal din<n−2> couples from the master latch 540 to a selected column in the (n−2)th GIO column group 555.

Suppose that the (n−1)th GIO column group 525 is not defective such that the decoded column redundancy address signal (fcol<n−1>) is not asserted. The redundancy logic and switching circuit 520 then passes the data input signal din<n−1> through to the (n−1)th GIO column group 525 during a write operation. But if the decoded column redundancy address signal (fcol<n−1>) is asserted, the redundancy logic and switching circuit 520 routes the data input signal din<n−1> to the redundancy logic and switching circuit 550 to be passed to the (n−2)th GIO column group 555. Similarly, if neither the (n−1)th GIO column group 525 nor the (n−2)th GIO column group 555 is defective such that the decoded column redundancy address signal (fcol<n−2>) is not asserted, then the redundancy logic and switching circuit 550 passes the data input signal din<n−2> to the (n−2)th GIO column group 555. However, if either the (n−1)th GIO column group 525 or the (n−2)th GIO column group 555 is defective, the din<n−2> signal couples instead to a selected column's bitcell (not illustrated) in the (n−3)th GIO column group (not illustrated).

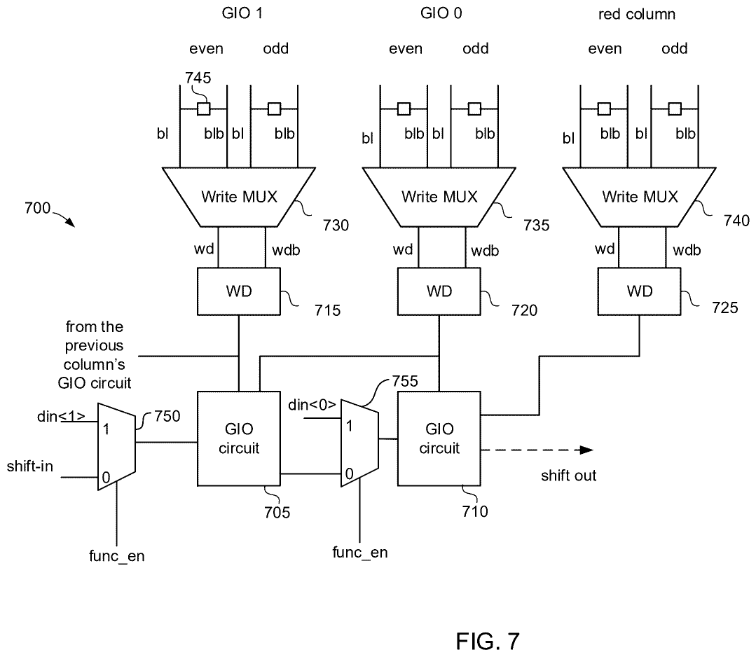

Another scan chain 700 that is integrated with the data path to the GIO column groups is shown in FIG. 7 for a memory in which each GIO column group is formed by two columns. For illustration clarity, the master and slave latches are not shown. Similarly, the redundancy and switching logic circuits are not shown for illustration brevity. Since there are just two columns in each GIO column group, one column of bitcells may be denoted as an even column and the remaining column in the pair may be denoted as an odd column. For example, a first GIO column group (GIO 1) includes an even column and an odd column that are selected from during a write operation by a write column multiplexer 730. Each column is traversed by a corresponding bit line pair formed by a bit line (bl) and a complement bit line (blb). A plurality of bitcells 745 within each column are arranged in rows (for illustration clarity, only one row of bitcells 745 is shown). During the functional mode, a multiplexer 750 selects a data input signal din<1> to be latched in a first GIO circuit 705. If the first GIO column is in the no-shift region, the data input signal din<1> is driven by a write driver 715 onto a write driver (wd) output terminal. The write driver 715 also drives a complement of the data input signal ding 1> onto a complement write driver (wdb) output terminal. Depending upon a write address, the write column multiplexer 730 selects between the columns. For example, if the even column is selected, the write column multiplexer 730 couples the write driver output terminal wd to the bit line bl in the even column and couples the complement write driver terminal wdb to the complement bit line blb in the even column.

However, if the first GIO column group is in the shift region, the data input signal din<1> from the first GIO circuit 705 is instead routed to a write driver 720 for a zeroth GIO column group (GIO 0). In that case, a zeroth data input signal din<0> selected during the functional mode by a multiplexer 755 to be latched into a zeroth GIO circuit 710 is routed from the zeroth GIO circuit 710 to a write driver 725 for a redundant GIO column group (red column). A write column multiplexer 740 selects between an even and odd column for the redundant GIO column group. During either the scan mode or the redundancy setup mode, the GIO circuits 705 and 710 would instead latch the shift-in signal as discussed with respect to the scan chain 500.

A reduction in the shift-in time through a splitting of a scan chain into separate portions will now be discussed. Should a scan chain extend across all the GIO circuits for a bank, the shifting in of the serialized decoded column redundancy address signal takes one clock cycle per GIO circuit. For example, the shifting in of the serialized decoded column redundancy address signal into the scan chain 500 requires at least n clock cycles, where n is the number of the GIO circuits. To reduce the number of clock cycles to shift in the serialized decoded column redundancy address signal, the serializer (e.g., the serializer 130 or the serializer 240) may increase the bit width of the serialized decoded column redundancy address signal. For example, suppose that there are eight GIO circuits shared between a pair of banks. The corresponding data in signals would then range from a data in signal din<7> to a data in signal din<0>. Similarly, a decoded column redundancy address signal faddr<7:0> for each bank would be eight bits wide. To reduce the shifting time, a serializer may be configured to serialize the decoded column redundancy address signal faddr<7:0> into an upper serialized decoded column redundancy address signal fcol_ser<7:4> and a lower serialized decoded column redundancy address signal fcol_ser<3:0>.

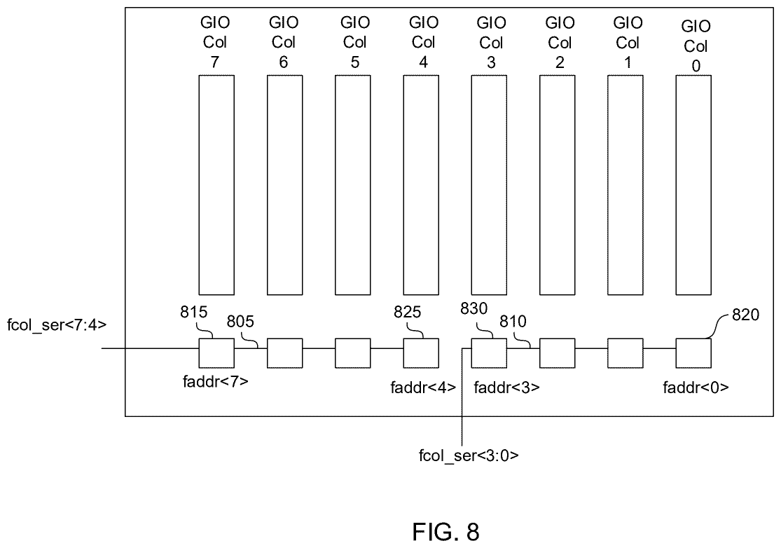

A corresponding bank 800 is shown in FIG. 8 that includes a first scan chain 805 and a second scan chain 810. The bank includes eight GIO column groups ranging from a seventh GIO column group (GIO col 7) to a zeroth GIO column group (GIO col 0). The GIO circuits for each bank may then be organized into the first scan chain 805 and the second scan chain 810. The first scan chain 805 may extend from a seventh GIO circuit 815 to a fourth GIO circuit 825 to receive the upper serialized decoded column redundancy address signal fcol_ser<7:4>. Similarly, the second scan chain may extend from a third GIO circuit 830 to a zeroth GIO circuit 820 to receive the lower serialized decoded column redundancy address signal fcol_ser<3:0>. In this fashion, the number of clock cycles to shift across a plurality of n GIO circuits is reduced from n clock cycles to n/2 clock cycles. It will be appreciated that the GIO circuits may be further divided into more than two scan chains to further reduce the shift in time. The serializer would be configured accordingly. Should there be two scan chains per bank, the corresponding serializer may be formed from two PISO shift registers analogously as discussed for the PISO shift register 140.

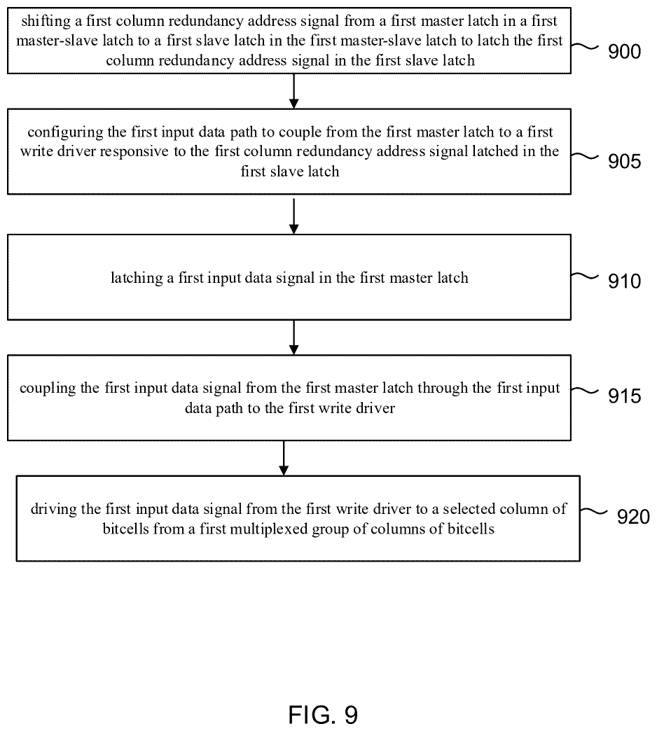

A method of using a first input data path in a memory to receive column redundancy address signals will now be discussed with reference to the flowchart of FIG. 9. The method includes a first series of acts 900 and 905 that are performed during a redundancy setup mode of operation for the memory. The act 900 includes shifting a first column redundancy address signal from a first master latch in a first master-slave latch to a first slave latch in the first master-slave latch to latch the first column redundancy address signal in the first slave latch. The shifting of the fcol<n−1> through the master latch 510 to be latched in the slave latch 515 is an example of act 900. The act 905 includes configuring the first input data path to couple from the first master latch to a first write driver responsive to the first column redundancy address signal latched in the first slave latch. The configuration by the redundancy logic and switching circuit 520 is an example of act 905.

The method also includes acts 910, 915, and 920 that are performed during a write operation to the memory. The act 910 includes latching a first input data signal in the first master latch. The latching of the din<n−1> signal in the master latch 510 is an example of act 910. The act 915 includes coupling the first input data signal from the first master latch through the first input data path to the first write driver. The coupling of the din<n−1> signal from the master latch 510 to one of the GIO column groups 525 and 555 is an example of act 915. Finally, the act 920 includes driving the first input data signal from the first write driver to a selected column of bitcells from a first multiplexed group of columns of bitcells. The writing of the din<n−1> signal to one of the GIO column groups 525 and 555 is an example of act 920.

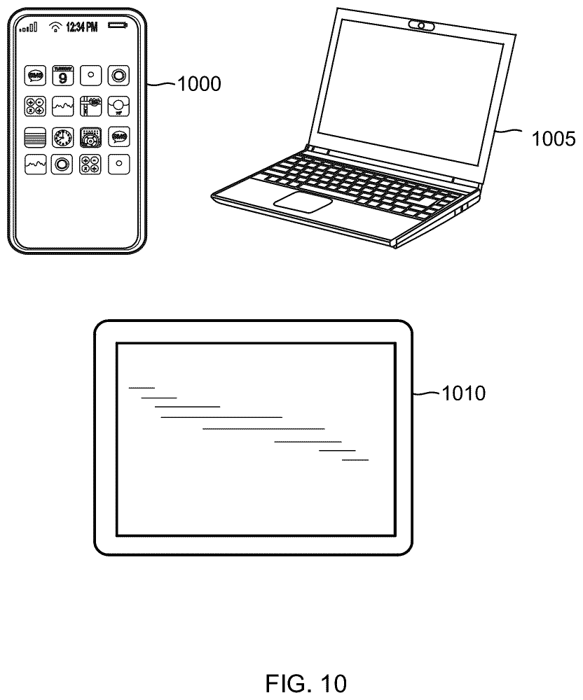

A memory as disclosed herein may be included into a wide variety of electronic systems. For example, as shown in FIG. 10, a cell phone 1000, a laptop 1005, and a tablet PC 1010 may all include a memory having a data path that is also used to shift in redundancy address signals in accordance with the disclosure. Other exemplary electronic systems such as a music player, a video player, a communication device, and a personal computer may also be configured with memories constructed in accordance with the disclosure.

The disclosure will now be summarized by the following example clauses:

Clause 1. A memory including a first bank, the first bank comprising:
a first multiplexed group of columns of bitcells;
a second multiplexed group of columns of bitcells;
a third multiplexed group of columns of bitcells;
a first scan chain configured to shift in a first column redundancy address bit and a second column redundancy address bit;
a first input data storage circuit configured to store a first input data signal to be coupled to one of the first multiplexed group of columns of bitcells and the second multiplexed group of columns according to a first column redundancy selection that is responsive to the first column redundancy address bit; and
a second input data storage circuit configured to store a second input data signal to be coupled to one of the second multiplexed group of columns of bitcells and the third multiplexed group of bitcells according to a second column redundancy selection that is responsive to the second column redundancy address bit, wherein the first input data storage circuit the second input data storage circuit are both included within the first scan chain.

Clause 2. The memory of clause 1, wherein the first input data storage circuit comprises a first input data flip-flop and the second input data storage circuit comprises a second input data flip-flop.

Clause 3. The memory of clause 2, wherein the first scan chain is further configured to shift in a scan-in signal.

Clause 4. The memory of any of clauses 2-3, wherein the first scan chain includes a first slave flip-flop coupled to the first input data flip-flop to form a first master-slave latch and includes a second slave flip-flop coupled to the second input data flip-flop to form a second master-slave latch, and wherein the first slave flip-flop is configured to latch the first column redundancy address bit and the second slave flip-flop is configured to latch the second column redundancy address bit.

Clause 5. The memory of clause 4, wherein the first input data flip-flop and the second input data flip-flop are both configured to be clocked by a master clock signal, the memory further comprising:
a clock multiplexer configured to select between the master clock signal and ground to form a slave clock signal for a clocking of the first slave flip-flop and the of the second slave flip-flop.

Clause 6. The memory of clause 5, wherein the clock multiplexer is configured to between the master clock signal and ground.

Clause 7. The memory of any of clauses 4-6, further comprising:
a first input multiplexer configured to select between the first input data signal and the first column redundancy address bit, the first input multiplexer having an output terminal coupled to an input terminal of the first master-slave latch; and
a second input multiplexer configured to select between the second input data signal and an output signal from the first master-slave latch, the second input multiplexer having an output terminal coupled to an input terminal of the second master-slave latch.

Clause 8. The memory of any of clauses 1-7, further comprising: a first redundancy logic and switching circuit operable to form the first column redundancy selection responsive to the first column redundancy address bit; and a second redundancy logic and switching circuit operable to form the second column redundancy selection responsive to the second column redundancy address bit.

Clause 9. The memory of clause 3, wherein the first column redundancy address bit and the second column redundancy address bit are included in a serialized decoded column redundancy address signal, the memory further comprising:
a first transmission gate configured to gate or pass the scan-in signal to the first scan chain; and
a second transmission gate configured to gate or pass the serialized decoded column redundancy address signal to the first scan chain.

Clause 10. The memory of clause 2, further comprising:
a first write column multiplexer configured to select for a column of bitcells from the first multiplexed group of columns of bitcells during a write operation;
a first write driver coupled to the first write column multiplexer;
a second write column multiplexer configured to select for a column of bitcells from the second multiplexed group of columns of bitcells during the write operation; and
a second write driver coupled to the second write column multiplexer.

Clause 11. The memory of clause 3, further comprising:
a second bank including a second scan chain;
a column redundancy address decoder configured to decode a first column redundancy address signal to provide a first decoded column redundancy address signal including the first column redundancy address bit and the second column redundancy address bit and configured to decode a second column redundancy address signal to provide a second decoded column redundancy address signal; and
a serializer configured to serialize the first decoded column redundancy address signal to form a first serialized decoded column redundancy address signal and to serialize the second decoded column redundancy address signal to form a second serialized decoded column redundancy address signal, wherein the first scan chain is configured to selectively shift in the first serialized decoded column redundancy address signal, and wherein the second scan chain is configured to selectively shift in the second serialized decoded column redundancy address signal.

Clause 12. The memory of any of clauses 1-12, wherein the memory is included within a cellular telephone.

Clause 13. A method of using a first input data path in a memory to receive column redundancy address signals, comprising:
shifting a first column redundancy address signal from a first master latch in a first master-slave latch to a first slave latch in the first master-slave latch to latch the first column redundancy address signal in the first slave latch;
configuring the first input data path to couple from the first master latch to a first write driver responsive to the first column redundancy address signal latched in the first slave latch;
latching a first input data signal in the first master latch;
coupling the first input data signal from the first master latch through the first input data path to the first write driver; and
driving the first input data signal from the first write driver to a selected column of bitcells from a first multiplexed group of columns of bitcells.

Clause 14. The method of clause 13, further comprising:
shifting in a scan-in signal through the first master-slave latch to a second master-slave latch.

Clause 15. The method of any of clauses 13-14, further comprising:
shifting a second column redundancy address signal from the first master-slave latch to a second master-slave latch to latch the second column redundancy address signal in a second slave latch in the second master-slave latch; and
configuring a second input data path to couple from a second master latch in the second master-slave latch to a second write driver responsive to the second column redundancy address signal latched in the second slave latch;
latching a second input data signal in the second master latch;
coupling the second input data signal from the second master latch through the second input data path to the second write driver; and
driving the second input data signal from the second write driver to a selected column of bitcells from a second multiplexed group of columns of bitcells.

Clause 16. A memory, comprising:
a first global input/output column group;
a second global input/output column group;
a scan chain including a plurality of master-slave latches arranged serially starting from a first master-slave latch;
a first global input/output circuit including a data input latch, wherein the data input latch is configured to function as a master latch in the first master-slave latch;
a first multiplexer configured to select between a data input signal and a serialized decoded column redundancy address signal, wherein the first multiplexer includes an output terminal coupled to a data input terminal of the data input latch, and
wherein a slave latch in the first master-slave latch is configured to latch a column redundancy address signal from the serialized decoded column redundancy address signal; and
a data path configured to couple from an output terminal of the data input latch to a selected one of the first global input/output column group and the second global input/output column group during the write operation according to a column redundancy selection responsive to the column redundancy address signal.

Clause 17. The memory of clause 16, wherein the column redundancy address signal is a one-bit signal, and wherein the data path is further configured to couple from the output terminal of the data input latch to the first global input/output column group during the write operation responsive to the one-bit signal being logically false.

Clause 18. The memory of clause 17, wherein the data path is further configured to couple from the output terminal of the data input latch to the second global input/output column group during the write operation responsive to the one-bit signal being logically true.

Clause 19. The memory of any of clauses 16-18, wherein the first global input/output column group and the second global input/output column group each comprises:
a write driver;
a write column multiplexer; and
a group of columns of bitcells, wherein the write column multiplexer is configured to select for a selected column of bitcells from the group of columns of bitcells and the write driver is configured to write to the selected column of bitcells during the write operation.

Clause 20. The memory of clause 19, wherein each column of bitcells in each group of columns of bitcells includes a pair of bit lines.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A memory including a first bank, the first bank comprising:
a first multiplexed group of columns of bitcells;
a second multiplexed group of columns of bitcells;
a third multiplexed group of columns of bitcells;
a first scan chain configured to shift in a first column redundancy address bit and a second column redundancy address bit;
a first input data storage circuit configured to store a first input data signal to be coupled to one of the first multiplexed group of columns of bitcells and the second multiplexed group of columns according to a first column redundancy selection that is responsive to the first column redundancy address bit; and
a second input data storage circuit configured to store a second input data signal to be coupled to one of the second multiplexed group of columns of bitcells and the third multiplexed group of bitcells according to a second column redundancy selection that is responsive to the second column redundancy address bit, wherein the first input data storage circuit the second input data storage circuit are both included within the first scan chain.

2. The memory of claim 1, wherein the first input data storage circuit comprises a first input data flip-flop and the second input data storage circuit comprises a second input data flip-flop.

3. The memory of claim 2, wherein the first scan chain is further configured to shift in a scan-in signal.

4. The memory of claim 2, wherein the first scan chain includes a first slave flip-flop coupled to the first input data flip-flop to form a first master-slave latch and includes a second slave flip-flop coupled to the second input data flip-flop to form a second master-slave latch, and wherein the first slave flip-flop is configured to latch the first column redundancy address bit and the second slave flip-flop is configured to latch the second column redundancy address bit.

5. The memory of claim 4, wherein the first input data flip-flop and the second input data flip-flop are both configured to be clocked by a master clock signal, the memory further comprising:
a clock multiplexer configured to select between the master clock signal and ground to form a slave clock signal for a clocking of the first slave flip-flop and the of the second slave flip-flop.

6. The memory of claim 5, wherein the clock multiplexer is configured to select between the master clock signal and ground during a write operation.

7. The memory of claim 4, further comprising:
a first input multiplexer configured to select between the first input data signal and the first column redundancy address bit, the first input multiplexer having an output terminal coupled to an input terminal of the first master-slave latch; and
a second input multiplexer configured to select between the second input data signal and an output signal from the first master-slave latch, the second input multiplexer having an output terminal coupled to an input terminal of the second master-slave latch.

8. The memory of claim 1, further comprising:
a first redundancy logic and switching circuit operable to form the first column redundancy selection responsive to the first column redundancy address bit; and
a second redundancy logic and switching circuit operable to form the second column redundancy selection responsive to the second column redundancy address bit.

9. The memory of claim 3, wherein the first column redundancy address bit and the second column redundancy address bit are included in a serialized decoded column redundancy address signal, the memory further comprising:
a first transmission gate configured to gate from or pass the scan-in signal to the first scan chain; and
a second transmission gate configured to gate or pass the serialized decoded column redundancy address signal to the first scan chain.

10. The memory of claim 2, further comprising:
a first write column multiplexer configured to select for a column of bitcells from the first multiplexed group of columns of bitcells during a write operation;
a first write driver coupled to the first write column multiplexer;
a second write column multiplexer configured to select for a column of bitcells from the second multiplexed group of columns of bitcells during the write operation; and
a second write driver coupled to the second write column multiplexer.

11. The memory of claim 3, further comprising:
a second bank including a second scan chain;
a column redundancy address decoder configured to decode a first column redundancy address signal to provide a first decoded column redundancy address signal including the first column redundancy address bit and the second column redundancy address bit and configured to decode a second column redundancy address signal to provide a second decoded column redundancy address signal; and
a serializer configured to serialize the first decoded column redundancy address signal to form a first serialized decoded column redundancy address signal and to serialize the second decoded column redundancy address signal to form a second serialized decoded column redundancy address signal, wherein the first scan chain is configured to shift in the first serialized decoded column redundancy address signal, and wherein the second scan chain is configured to shift in the second serialized decoded column redundancy address signal.

12. The memory of claim 1, wherein the memory is included within a cellular telephone.

13. A method of using a first input data path in a memory to receive column redundancy address signals, comprising:
shifting a first column redundancy address signal from a first master latch in a first master-slave latch to a first slave latch in the first master-slave latch to latch the first column redundancy address signal in the first slave latch;
configuring the first input data path to couple from the first master latch to a first write driver responsive to the first column redundancy address signal latched in the first slave latch;
latching a first input data signal in the first master latch;
coupling the first input data signal from the first master latch through the first input data path to the first write driver; and
driving the first input data signal from the first write driver to a selected column of bitcells from a first multiplexed group of columns of bitcells.

14. The method of claim 13, further comprising:
shifting in a scan-in signal through the first master-slave latch to a second master-slave latch.

15. The method of claim 13, further comprising:
shifting a second column redundancy address signal from the first master-slave latch to a second master-slave latch to latch the second column redundancy address signal in a second slave latch in the second master-slave latch;
configuring a second input data path to couple from a second master latch in the second master-slave latch to a second write driver responsive to the second column redundancy address signal latched in the second slave latch;
latching a second input data signal in the second master latch;
coupling the second input data signal from the second master latch through the second input data path to the second write driver; and
driving the second input data signal from the second write driver to a selected column of bitcells from a second multiplexed group of columns of bitcells.

16. A memory, comprising:
a first global input/output column group;
a second global input/output column group;
a scan chain including a plurality of master-slave latches arranged serially starting from a first master-slave latch;
a first global input/output circuit including a data input latch, wherein the data input latch is configured to function as a master latch in the first master-slave latch;
a first multiplexer configured to select between a data input signal and a serialized decoded column redundancy address signal, wherein the first multiplexer includes an output terminal coupled to a data input terminal of the data input latch, and wherein a slave latch in the first master-slave latch is configured to latch a column redundancy address signal from the serialized decoded column redundancy address signal; and
a data path configured to couple from an output terminal of the data input latch to a selected one of the first global input/output column group and the second global input/output column group according to a column redundancy selection that is responsive to the column redundancy address signal.

17. The memory of claim 16, wherein the column redundancy address signal is a one-bit signal, and wherein the data path is further configured to couple from the output terminal of the data input latch to the first global input/output column group during the write operation responsive to the one-bit signal being logically false.

18. The memory of claim 17, wherein the data path is further configured to couple from the output terminal of the data input latch to the second global input/output column group during the write operation responsive to the one-bit signal being logically true.

19. The memory of claim 16, wherein the first global input/output column group and the second global input/output column group each comprises:
a write driver;
a write column multiplexer; and
a group of columns of bitcells, wherein the write column multiplexer is configured to select for a selected column of bitcells from the group of columns of bitcells and the write driver is configured to write to the selected column of bitcells during the write operation.

20. The memory of claim 19, wherein each column of bitcells in each group of columns of bitcells includes a pair of bit lines.
